(19) United States
(12) Patent Application Publication
(10) Pub. No.: US 2024/0357799 A1
(43) Pub. Date: Oct. 24, 2024

(54) SEMICONDUCTOR MEMORY DEVICE

(71) Applicant: Samsung Electronics Co., Ltd., Suwon-si (KR)

(72) Inventors: Choong Hyun LEE, Suwon-si (KR); Joon Cheol KIM, Suwon-si (KR); Kang-Uk KIM, Suwon-si (KR); Jin A KIM, Suwon-si (KR); Byoung Wook JANG, Suwon-si (KR); Young-Seung CHO, Suwon-si (KR)

(73) Assignee: Samsung Electronics Co., Ltd., Suwon-si (KR)

(21) Appl. No.: 18/508,833

(22) Filed: Nov. 14, 2023

(30) Foreign Application Priority Data
Apr. 24, 2023 (KR) 10-2023-0053095

(51) Int. Cl. H10B 12/00; G11C 5/06

(52) U.S. Cl. CPC H10B 12/482; G11C 5/063; H10B 12/315; H10B 12/485; H10B 12/488; H10B 12/50

(57) ABSTRACT

There is provided a semiconductor memory device capable of improving performance and reliability of an element. The semiconductor memory device includes a substrate including a cell region and a peripheral region, a cell region isolation layer in the substrate, isolating the cell region from the peripheral region, an isolation active region surrounded by the cell region isolation layer, a bit line structure on the cell region, including a cell conductive line and a cell gate electrode in the substrate of the cell region, crossing the cell conductive line.

### CROSS-REFERENCE TO RELATED APPLICATION

This application claims priority from Korean Patent Application No. 10-2023-0053095 filed on Apr. 24, 2023 in the Korean Intellectual Property Office and all the benefits accruing therefrom under 35 U.S.C. 119, the contents of which in its entirety are herein incorporated by reference.

### BACKGROUND

The present disclosure relates to a semiconductor memory device.

As semiconductor devices become increasingly highly integrated, individual circuit patterns are becoming finer to implement more semiconductor devices in the same area. That is, with the increase in the degree of integration of the semiconductor device, the design rule for components of the semiconductor device has been reduced.

In highly scaled semiconductor devices, a process of forming a plurality of wiring lines and a plurality of buried contacts (BC) interposed between the wiring lines has become increasingly complex and difficult.

### SUMMARY

One or more example embodiments of the present disclosure provide a semiconductor memory device that may improve reliability and performance.

One or more example embodiments of the present disclosure are not limited to those mentioned above and additional objects of the present disclosure, which are not mentioned herein, will be clearly understood by those skilled in the art from the following description of the present disclosure.

According to some aspects of the present disclosure, there is provided a semiconductor memory device comprising a substrate including a cell region and a peripheral region, a cell region isolation layer in the substrate, isolating the cell region from the peripheral region, an isolation active region surrounded by the cell region isolation layer, a bit line structure on the cell region, including a cell conductive line and a cell gate electrode in the substrate of the cell region, crossing the cell conductive line.

According to another aspect of the present disclosure, there is provided a semiconductor memory device comprising a substrate including a cell region and a peripheral region, a cell region isolation layer in the substrate, including a first sub-region isolation layer and a second sub-region isolation layer, which are spaced apart from each other in a first direction, and isolating the cell region from the peripheral region, an isolation active region between the first sub-region isolation layer and the second sub-region isolation layer, a cell conductive line on the cell region and extending in the first direction and a cell gate electrode in the substrate of the cell region and extending in a second direction.

According to still another aspect of the present disclosure, there is provided a semiconductor memory device comprising a substrate including a cell region and a peripheral region, a cell region isolation layer disposed in the substrate, isolating the cell region from the peripheral region, an isolation active region surrounded by the cell region isolation layer, a plurality of cell conductive lines on the cell region and extending in a first direction, a plurality of cell gate electrodes in the substrate of the cell region and extending in a second direction; and a plurality of cell conductive plugs on the cell conductive line and respectively connected to the cell conductive lines, wherein each cell conductive line includes a first longitudinal end and a second longitudinal end, the first longitudinal end of the cell conductive line is spaced apart from the second longitudinal end of the cell conductive line in the first direction, the plurality of cell conductive lines include a first cell conductive line and a second cell conductive line, which are adjacent to each other in the second direction, the first longitudinal end of the first cell conductive line is on the isolation active region, and the first longitudinal end of the second cell conductive line is on the cell region isolation layer.

Other specific details of the disclosure are included in the detailed description and drawings.

### BRIEF DESCRIPTION OF DRAWINGS

FIG. 1 is a schematic layout illustrating a semiconductor memory device according to some example embodiments.

FIG. 2 is a schematic layout illustrating a region R1 of FIG. 1.

FIG. 3 is a layout illustrating only a word line and a cell active region of FIG. 2.

FIG. 4 is a schematic layout illustrating a region R2 of FIG. 1.

FIG. 5 is a schematic layout illustrating a region R3 of FIG. 1.

FIG. 6 is a cross-sectional view taken along line A-A of FIG. 4.

FIG. 7 is a cross-sectional view taken along line B-B of FIG. 4.

FIG. 8 is a cross-sectional view taken along line C-C of FIG. 4.

FIG. 9 is an example cross-sectional view taken along line D-D of FIG. 5.

FIG. 10 is an example cross-sectional view taken along line E-E of FIG. 5.

FIG. 11 is a view illustrating a connection relation between adjacent bit lines of FIG. 4 and a cell conductive line plug connected to each bit line.

FIG. 12 is a view illustrating a semiconductor memory device according to some example embodiments.

FIG. 13 is a view illustrating a semiconductor memory device according to some example embodiments.

FIG. 14 is a view illustrating a semiconductor memory device according to some example embodiments.

FIGS. 15 and 16 are views illustrating a semiconductor memory device according to some example embodiments.

FIGS. 17 to 22 are views illustrating an effect due to arrangement of an isolation active region according to some example embodiments.

FIGS. 23 to 25 are views illustrating a method for fabricating a semiconductor memory device according to some example embodiments.

FIGS. 26 and 27 are views illustrating a method for fabricating a semiconductor memory device according to some example embodiments.

FIGS. 28 and 29 are views illustrating a method for fabricating a semiconductor memory device according to some example embodiments.

### DETAILED DESCRIPTION

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

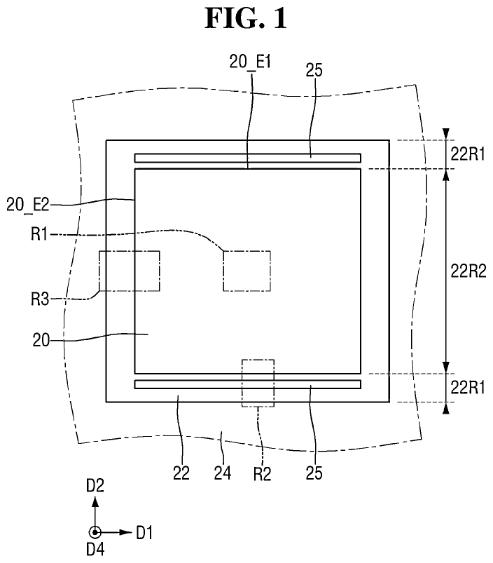

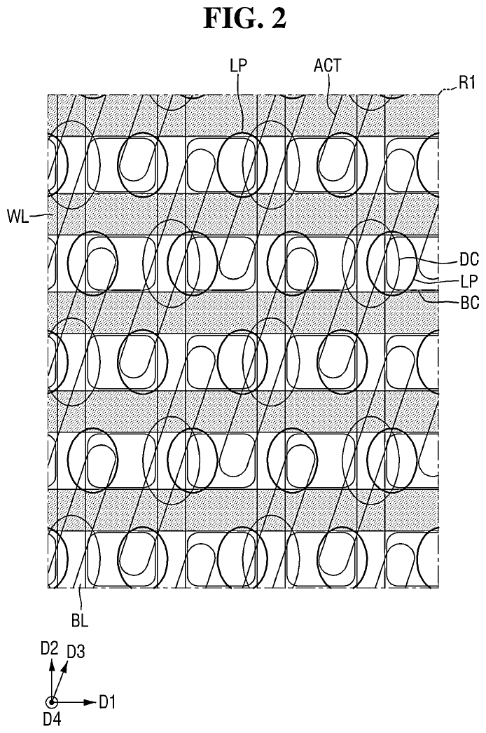

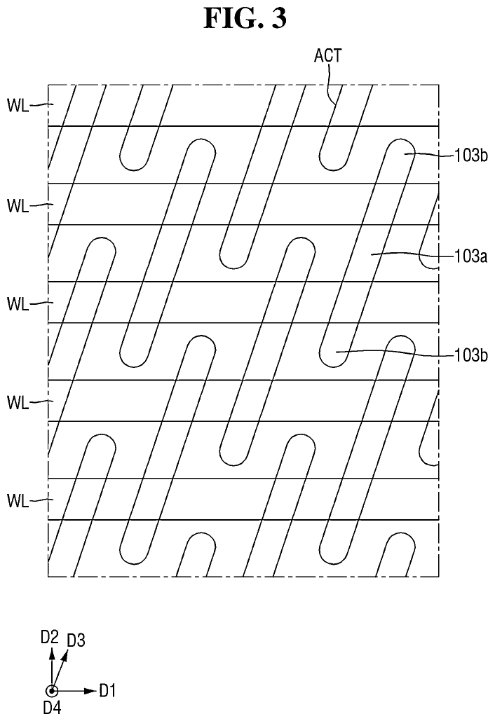

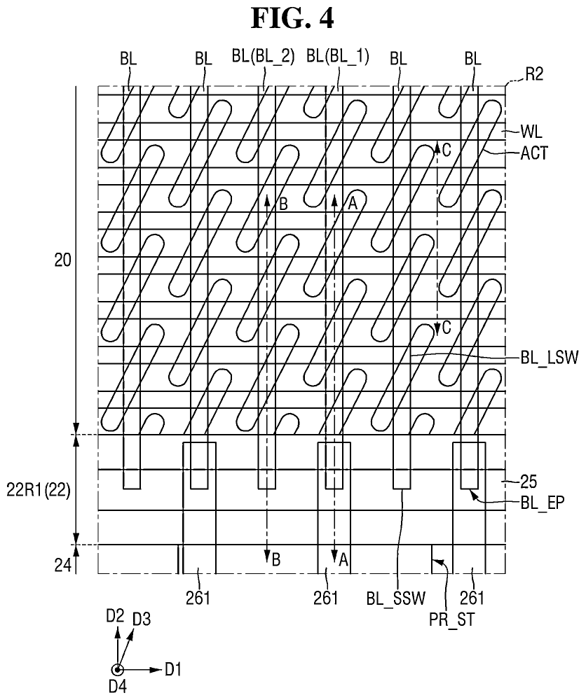

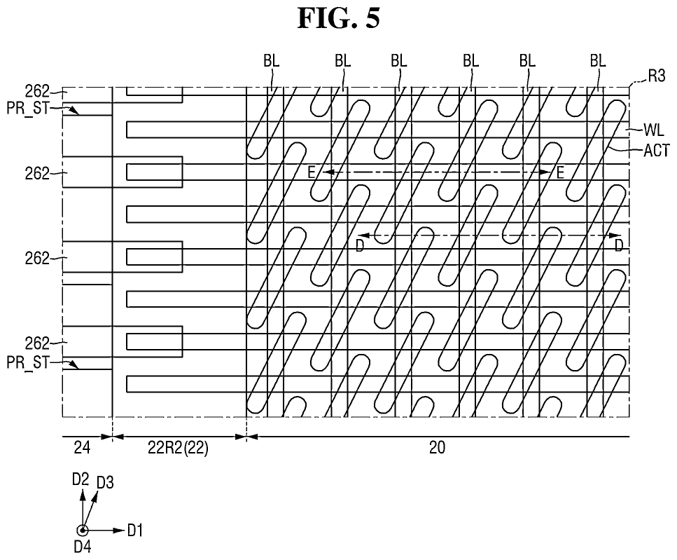

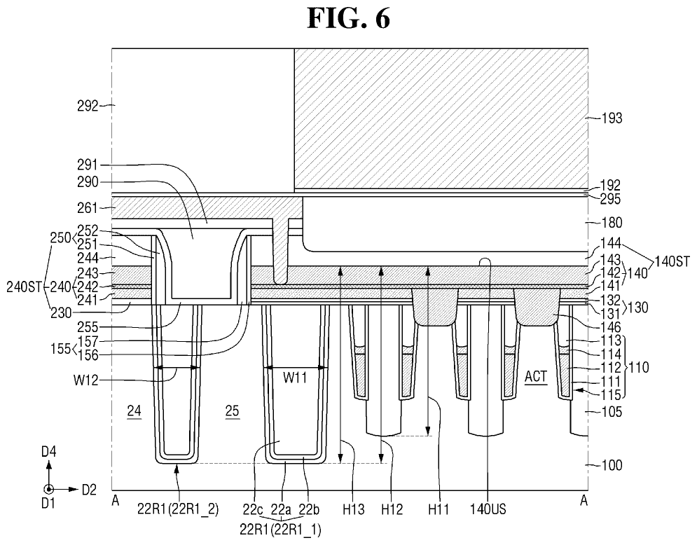

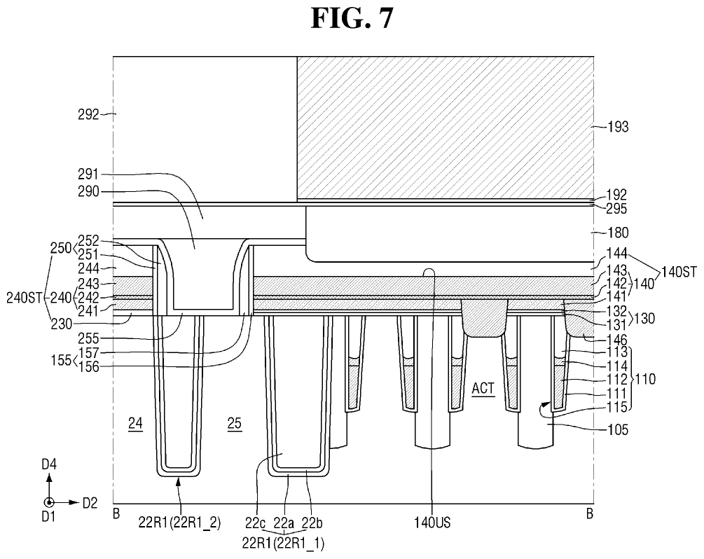

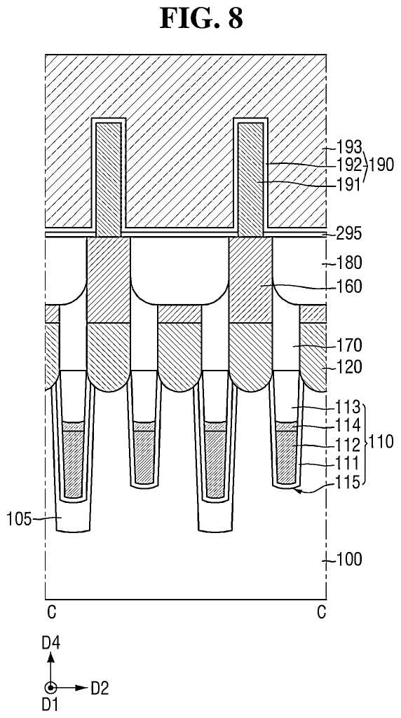

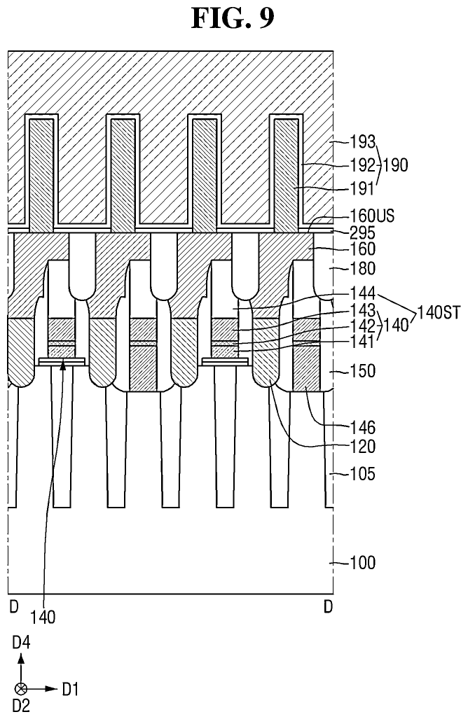

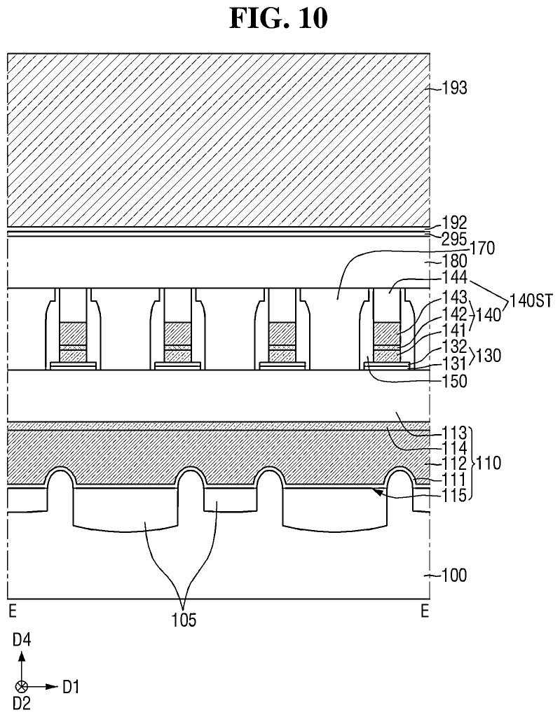

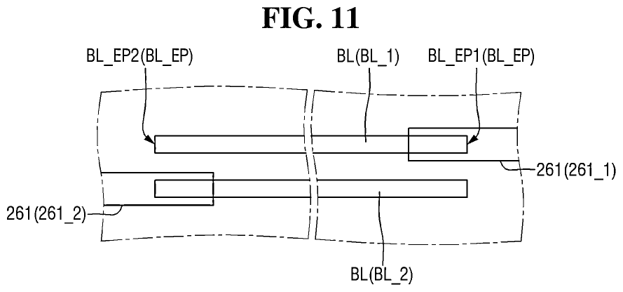

FIG. 1 is a schematic layout illustrating a semiconductor memory device according to some example embodiments. FIG. 2 is a schematic layout illustrating a region R1 of FIG. 1. FIG. 3 is a layout illustrating only a word line and a cell active region of FIG. 2. FIG. 4 is a schematic layout illustrating a region R2 of FIG. 1. FIG. 5 is a schematic layout illustrating a region R3 of FIG. 1. FIG. 6 is a cross-sectional view taken along line A-A of FIG. 4. FIG. 7 is a cross-sectional view taken along line B-B of FIG. 4. FIG. 8 is a cross-sectional view taken along line C-C of FIG. 4. FIG. 9 is an example cross-sectional view taken along line D-D of FIG. 5. FIG. 10 is an example cross-sectional view taken along line E-E of FIG. 5. FIG. 11 is a view illustrating a connection relation between adjacent bit lines of FIG. 4 and a cell conductive line plug connected to each bit line.

For reference, a landing pad LP, a buried contact BC and a direct contact DC are not shown in FIGS. 4 and 5.

Although a dynamic random access memory (DRAM) is shown in the drawings related to a semiconductor memory device according to some example embodiments, the present disclosure is not limited thereto.

Referring to FIGS. 1 to 5 and 11, a semiconductor memory device according to some example embodiments may include a cell region 20, a cell region isolation layer 22, a peripheral region 24, and an isolation active region 25.

The cell region isolation layer 22 may be formed along the periphery of the cell region 20. The cell region isolation layer 22 may isolation the cell region 20 from the peripheral region 24. The cell region 20 may be defined by the cell region isolation layer 22. The peripheral region 24 may be defined in the periphery of the cell region 20.

The cell region isolation layer 22 includes a first portion 22R1 and a second portion 22R2. The first portion 22R1 of the cell region isolation layer may be a portion of the cell region isolation layer 22, which is extended in a first direction D1. The second portion 22R2 of the cell region isolation layer may be a portion of the cell region isolation layer 22, which is extended in a second direction D2.

The cell region 20 may include a first boundary surface 20_E1 extended in the first direction D1 and a second boundary surface 20_E2 extended in the second direction D2. The first boundary surface 20_E1 of the cell region and the second boundary surface 20_E2 of the cell region are boundaries of the cell region 20 and the cell region isolation layer 22.

The first boundary surface 20_E1 of the cell region may form a boundary with the first portion 22R1 of the cell region isolation layer. The second boundary surface 20_E2 of the cell region may form a boundary with the second portion 22R2 of the cell region isolation layer.

The isolation active region 25 may be surrounded by the cell region isolation layer 22. In a plan view, the isolation active region 25 may be positioned in the cell region isolation layer 22.

The isolation active region 25 may be disposed in the first portion 22R1 of the cell region isolation layer. The first portion 22R1 of the cell region isolation layer may surround the isolation active region 25. The isolation active region 25 may not be disposed in the second portion 22R2 of the cell region isolation layer.

In the semiconductor memory device according to some example embodiments, in a plan view, the isolation active region 25 may be disposed in each of the first portions 22R1 of the cell region isolation layer, which are spaced apart from each other in the second direction D2.

The isolation active region 25 may be extended in the first direction D1. In a plan view, the isolation active region 25 may have a line shape extended in the first direction D1.

The cell region 20 may include a plurality of cell active regions ACT. The cell active region ACT may be defined by a cell element isolation layer (105 of FIGS. 6 to 10) formed in a substrate (100 of FIGS. 6 to 10). As a semiconductor memory device is reduced, as shown, the cell active region ACT may be disposed in a bar shape of a diagonal line or an oblique line on a plane. For example, the cell active region ACT may be extended in a third direction D3.

A plurality of gate electrodes extended in the first direction D1 may be disposed across the cell active region ACT. The plurality of gate electrodes may be extended in parallel with each other. The plurality of gate electrodes may be, for example, a plurality of word lines WL. The word lines WL may be disposed at constant intervals. A width of the word line WL or an interval between the word lines WL may be determined in accordance with the inventive concepts.

The word line WL may be extended to the cell region isolation layer 22. A portion of the word line WL may overlap the cell region isolation layer 22 in a fourth direction D4. For example, the word line WL may overlap the second portion 22R2 of the cell region isolation layer in the fourth direction D4.

Each cell active region ACT may be divided into three portions by two word lines WL extended in the first direction D1. The cell active region ACT may include a storage connection region 103b and a bit line connection region 103a. The bit line connection region 103a may be positioned at a center portion of the cell active region ACT, for example between the two word lines, and the storage connection region 103b may be positioned at an end portion of the cell active region ACT, for example outside of the two word lines.

A plurality of bit lines BL extended in the second direction D2 orthogonal to the word line WL may be disposed on the word line WL. The plurality of bit lines BL may be extended in parallel with each other. The bit lines BL may be disposed at constant intervals. A width of the bit line BL or an interval between the bit lines BL may be determined in accordance with the inventive concepts.

The bit line BL may include a long sidewall BL_LSW extended in the second direction D2 and a short sidewall BL_SSW extended in the first direction D1. The bit line BL may include a longitudinal end BL_EP that includes a short sidewall BL_LSW of the bit line.

The bit line BL may be extended to the cell region isolation layer 22. A portion of the bit line BL may overlap the cell region isolation layer 22 in the fourth direction D4. For example, the bit line BL may overlap the first portion 22R1 of the cell region isolation layer in the fourth direction D4.

Another portion of the bit line BL may be disposed on the isolation active region 25. Another portion of the bit line BL may overlap the isolation active region 25 in the fourth direction D4. Another portion of the bit line BL includes the longitudinal end BL_EP of the bit line. The end BL_EP of the bit line may be disposed on the isolation active region 25.

In the semiconductor memory device according to some example embodiments, in a plan view, the longitudinal end BL_EP of the bit line is positioned on the isolation active region 25, and may not be positioned on the first portion 22R1 of the cell region isolation layer.

The fourth direction D4 may be orthogonal to the first direction D1, the second direction D2 and the third direction D3. The fourth direction D4 may be a thickness direction of the substrate 100.

A peripheral gate structure 240ST (See FIG. 6) may be disposed on the peripheral region 24. A portion of the peripheral gate structure 240ST may be disposed at a boundary between the cell region isolation layer 22 and the peripheral region 24.

The semiconductor memory device according to some example embodiments may include various contact arrangements formed on the cell active region ACT. The various contact arrangements may include, for example, a direct contact DC, a buried contact BC, and a landing pad LP.

In this case, the direct contact DC may refer to a contact that electrically connects the cell active region ACT to the bit line BL. The buried contact BC may refer to a contact that connects the cell active region ACT to a lower electrode (191 of FIGS. 8 and 9) of an information storage. A contact area between the buried contact BC and the cell active region ACT may be small in view of an arrangement structure. As a result, a conductive landing pad LP may be introduced to enlarge a contact area with the lower electrode (191 of FIGS. 8 and 9) of the information storage and a contact area with the cell active region ACT.

The landing pad LP may be disposed between the cell active region ACT and the buried contact BC. Additionally, the landing pad LP may be disposed between the buried contact BC and the lower electrode (191 of FIGS. 8 and 9) of the information storage. In the semiconductor memory device according to some example embodiments, the landing pad LP may be disposed between the buried contact BC and the lower electrode of the information storage. As the contact area is enlarged through the introduction of the landing pad LP, contact resistance between the cell active region ACT and the lower electrode of the information storage may be reduced.

The direct contact DC may be connected to the bit line connection region 103a. The buried contact BC may be connected to the storage connection region 103b. As the buried contact BC is disposed at both end portions of the cell active region ACT, the landing pad LP may be disposed to partially overlap the buried contact BC in a state that it is adjacent to both ends of the cell active region ACT. In other words, the buried contact BC may be formed to overlap the cell active region ACT and the cell element isolation layer (105 of FIG. 9) between adjacent word lines WL and between adjacent bit lines BL.

The word line WL may be formed in a structure buried in the substrate 100. The word line WL may be disposed across the cell active region ACT between the direct contacts DC or the buried contacts BC. As shown, two word lines WL may be disposed to cross one cell active region ACT. As the cell active region ACT is extended along the third direction DR3, the word line WL may have an angle less than 90° with the cell active region ACT.

The direct contact DC and the buried contact BC may be symmetrically disposed. For this reason, the direct contact DC and the buried contact BC may be disposed on a straight line along the first direction D1 and the second direction D2. Unlike the direct contact DC and the buried contact BC, the landing pad LP may be disposed in a zigzag shape in the second direction D2 in which the bit line BL is extended. In addition, the landing pad LP may be disposed to overlap the same side portion of each bit line BL in the first direction D1 in which the word line WL is extended. For example, each landing pad LP of a first line may overlap a left side of a corresponding bit line BL, and each landing pad LP of a second line may overlap a right side of a corresponding bit line BL.

A plurality of bit line contact plugs 261 may be disposed on the bit line BL. Each bit line contact plug 261 may be connected to the bit line BL. The bit line contact plug 261 may be connected to the bit line BL near the longitudinal end BL_EP of the bit line.

In FIGS. 4 and 11, the bit line BL may include a first bit line BL_1 and a second bit line BL_2, which are most adjacent to each other in the first direction D1. The bit line BL includes a first longitudinal end BL_EP1 and a second longitudinal end BL_EP2. The first longitudinal end BL_EP1 of the bit line is positioned to be opposite to the second longitudinal end BL_EP2 of the bit line in the second direction D2. The first longitudinal end BL_EP1 of the bit line is spaced apart from the second longitudinal end BL_EP2 of the bit line in the second direction D2. The first longitudinal end BL_EP1 of the first bit line BL_1 and the first longitudinal end BL_EP1 of the second bit line BL_2 may be aligned along the first direction D1. The second longitudinal end BL_EP2 of the first bit line BL_1 and the second longitudinal end BL_EP2 of the second bit line BL_2 may be aligned along the first direction D1.

The bit line contact plug 261 may include a first bit line contact plug 261_1 connected to the first bit line BL_1 and a second bit line contact plug 261_2 connected to the second bit line BL_2. The first bit line contact plug 261_1 may be connected to the first bit line BL_1 near the first longitudinal end BL_EP1 of the first bit line BL_1. The first bit line contact plug 261_1 may not be connected to the first bit line BL_1 near the second longitudinal end BL_EP2 of the first bit line BL_1. The second bit line contact plug 261_2 may be connected to the second bit line BL_2 near the second longitudinal end BL_EP2 of the second bit line BL_2. The second bit line contact plug 261_2 may not be connected to the second bit line BL_2 near the first longitudinal end BL_EP1 of the second bit line BL_2.

A word line contact plug 262 may be disposed on the word line WL. Each word line contact plug 262 may be connected to the word line WL. The word line contact plug 262 may be connected to the word line WL near the longitudinal end of the word line WL.

The word line WL may include a first word line and a second word line, which are most adjacent to each other in the second direction D2. Each word line WL may include a first longitudinal end and a second longitudinal end, which are spaced apart from each other in the first direction D1. The word line contact plug 262 may be connected to the first word line near the first longitudinal end of the first word line. The word line contact plug 262 may not be connected to the second word line near the first longitudinal end of the second word line. The word line contact plug 262 may be connected to the second word line near the second longitudinal end of the second word line.

A boundary peripheral gate PR_ST may be disposed in the peripheral region 24. The boundary peripheral gate PR_ST is shown as being disposed along the boundary between the peripheral region 24 and the cell region isolation layer 22, but is only for convenience of description, and example embodiments are not limited thereto.

Referring to FIGS. 1 to 11, the semiconductor memory device according to some example embodiments may include a plurality of cell gate structures 110, a plurality of cell conductive lines 140, a plurality of storage pads 160, an information storage 190, and a peripheral gate conductive layer 240.

The substrate 100 includes a cell region 20 and a peripheral region 24. The substrate 100 may be a silicon substrate or a silicon-on-insulator (SOI). Alternatively, the substrate 100 may include, but is not limited to, silicon germanium, silicon germanium on insulator (SGOI), indium antimonide, lead telluride compound, indium arsenide, indium phosphide, gallium arsenide, or gallium antimonide.

The plurality of cell gate structures 110, the plurality of cell conductive lines 140, the plurality of storage pads 160, and the information storage 190 may be disposed in the cell region 20. The peripheral gate conductive layer 240 may be disposed in the peripheral region 24.

The cell element isolation layer 105 may be formed in the substrate 100 of the cell region 20. The cell element isolation layer 105 may have a shallow trench isolation (STI) structure having excellent element isolation characteristics. The cell element isolation layer 105 may define the cell active region ACT in the cell region 20.

The cell active region ACT may have an oblique shape so as to have an angle less than 90° with respect to the word line WL disposed in the cell element isolation layer 105. The cell active region ACT may have an oblique shape so as to have an angle less than 90° with respect to the bit line BL disposed on the cell element isolation layer 105. In other words, the cell active region ACT may have an oblique shape so as to have an angle less than 90° with respect to the cell gate structure 110 disposed in the cell element isolation layer 105. The cell active region ACT may have an oblique shape so as to have an angle less than 90° with respect to the bit line structure 140ST formed on the cell element isolation layer 105.

The cell element isolation layer 105 may include, but is not limited to, at least one of a silicon oxide layer, a silicon nitride layer or a silicon oxynitride layer. In FIGS. 6 to 10, the cell element isolation layer 105 is shown as being formed of one insulating layer, but is only for convenience of description and is not limited thereto. The cell element isolation layer 105 may be formed of one insulating layer or a plurality of insulating layers depending on a width of the cell element isolation layer 105.

The cell region isolation layer 22 may have an STI structure like the cell element isolation layer 105. The cell region isolation layer 22 isolates the cell region 20 from the peripheral region 24. The cell region isolation layer 22 may include a first liner isolation layer 22a, a second liner isolation layer 22b, and a filling isolation layer 22c.

The second liner isolation layer 22b may be disposed between the first liner isolation layer 22a and the filling isolation layer 22c. Each of the first liner isolation layer 22a and the second liner isolation layer 22b may be extended along sidewalls and a bottom surface of the filling isolation layer 22c.

The first liner isolation layer 22a and the filling isolation layer 22c may include, but are not limited to, silicon oxide. The second liner isolation layer 22b may include, but is not limited to, silicon nitride.

Each of the first portion 22R1 of the cell region isolation layer and the second portion 22R2 of the cell region isolation layer may include a first liner isolation layer 22a, a second liner isolation layer 22b, and a filling isolation layer 22c.

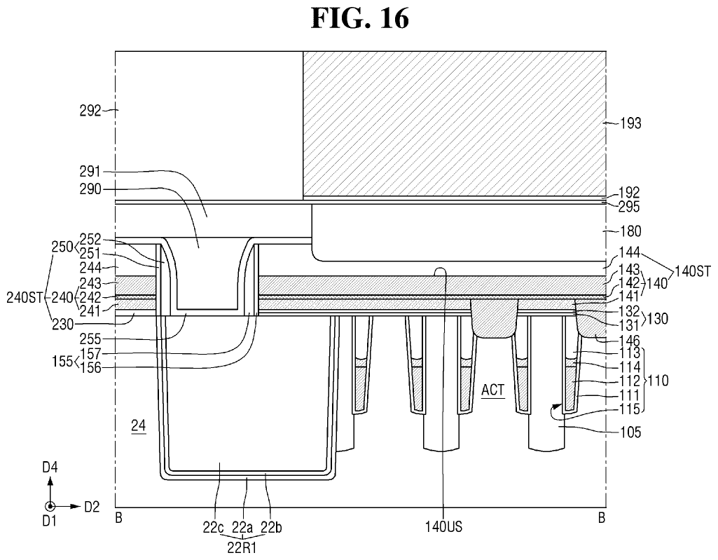

The cross-sectional view of the second portion 22R2 of the cell region isolation layer, which is cut in the first direction D1, may be similar to the cross-section of the first portion 22R1 of the cell region isolation layer, which is shown in FIG. 16.

Hereinafter, a cross-sectional shape in which the first portion 22R1 of the cell region isolation layer is cut in the second direction D2 will be described.

The first portion 22R1 of the cell region isolation layer may include a first sub-region isolation layer 22R1_1 and a second sub-region isolation layer 22R1_2, which are disposed in the substrate 100. The first sub-region isolation layer 22R1_1 may be spaced apart from the second sub-region isolation layer 22R1_2 in the second direction D2. The first sub-region isolation layer 22R1_1 may be more adjacent to the cell region 20 than the second sub-region isolation layer 22R1_2. It seems that the first sub-region isolation layer 22R1_1 and the second sub-region isolation layer 22R1_2 are isolated from each other in view of a cross-sectional view. However, the first sub-region isolation layer 22R1_1 and the second sub-region isolation layer 22R1_2 are connected to each other in view of a plan view.

Each of the first sub-region isolation layer 22R1_1 and the second sub-region isolation layer 22R1_2 may include a first liner isolation layer 22a, a second liner isolation layer 22b, and a filling isolation layer 22c. In the first sub-region isolation layer 22R1_1, each of the first liner isolation layer 22a and the second liner isolation layer 22b may be extended along the sidewalls and the bottom surface of the filling isolation layer 22c. Likewise, in the second sub-region isolation layer 22R1_2, the first liner isolation layer 22a and the second liner isolation layer 22b may be extended along the sidewalls and the bottom surface of the filling isolation layer 22c.

For example, a width W11 of the first sub-region isolation layer 22R1_1 in the second direction D2 may be different from a width W12 of the second sub-region isolation layer 22R1_2 in the second direction D2. For another example, the width W11 of the first sub-region isolation layer 22R1_1 in the second direction D2 may be the same as the width W12 of the second sub-region isolation layer 22R1_2 in the second direction D2. The width W11 of the first sub-region isolation layer 22R1_1 and the width W12 of the second sub-region isolation layer 22R1_2 may be measured at the same vertical level.

A depth H12 from an upper surface 140US of the cell conductive line to a lowermost portion of the first sub-region isolation layer 22R1_1 is greater than a depth H11 from the upper surface 140US of the cell conductive line to the lowermost portion of the cell element isolation layer 105. A depth H13 from the upper surface 140US of the cell conductive line to a lowermost portion of the second sub-region isolation layer 22R1_2 is greater than the depth H11 from the upper surface 140US of the cell conductive line to the lowermost portion of the cell element isolation layer 105. In the semiconductor memory device according to some example embodiments, the depth H12 from the upper surface 140US of the cell conductive line to the lowermost portion of the first sub-region isolation layer 22R1_1 may be the same as the depth H13 from the upper surface 140US of the cell conductive line to the lowermost portion of the second sub-region isolation layer 22R1_2.

The isolation active region 25 may be disposed between the cell region 20 and the peripheral region 24. The isolation active region 25 may be a portion of the substrate 100. In a cross-sectional view, the isolation active region 25 may be disposed between the first sub-region isolation layer 22R1_1 and the second sub-region isolation layer 22R1_2. In a plan view, the first sub-region isolation layer 22R1_1 and the second sub-region isolation layer 22R1_2 may surround the isolation active region 25.

The plurality of cell gate structures 110 may be formed in the substrate 100 and the cell element isolation layer 105. The cell gate structure 110 may be formed across the cell element isolation layer 105 and the cell active region ACT defined by the cell element isolation layer 105.

Although not shown, a portion of the cell gate structure 110 may be disposed in the cell region isolation layer 22. A portion of the cell gate structure 110 may be disposed in the second portion 22R2 of the cell region isolation layer.

The cell gate structure 110 may include a cell gate trench 115, a cell gate insulating layer 111, a cell gate electrode 112, a cell gate capping pattern 113 and a cell gate capping conductive layer 114, which are formed in the substrate 100 and the cell element isolation layer 105. In this case, the cell gate electrode 112 may correspond to the word line WL. Unlike the shown example embodiments, the cell gate structure 110 may not include the cell gate capping conductive layer 114.

The cell gate insulating layer 111 may be extended along sidewalls and a bottom surface of the cell gate trench 115. The cell gate insulating layer 111 may be extended along a profile of at least a portion of the cell gate trench 115. The cell gate insulating layer 111 may include at least one of, for example, silicon oxide, silicon nitride, silicon oxynitride, or a high dielectric constant material having a dielectric constant higher than that of silicon oxide. The high dielectric constant material may include at least one of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or their combination.

The cell gate electrode 112 may be disposed on the cell gate insulating layer 111. The cell gate electrode 112 may fill a portion of the cell gate trench 115. The cell gate capping conductive layer 114 may be extended along an upper surface of the cell gate electrode 112.

The cell gate electrode 112 includes a conductive material, and may include at least one of, for example, doped polysilicon, conductive metal nitride, conductive metal silicon nitride, metal carbonitride, conductive metal silicide, conductive metal oxide, two-dimensional material, metal or metal alloy. The cell gate capping conductive layer 114 may include, for example, polysilicon or polysilicon-germanium, but is not limited thereto.

The cell gate capping pattern 113 may be disposed on the cell gate electrode 112 and the cell gate capping conductive layer 114. The cell gate capping pattern 113 may fill the cell gate trench 115 remaining after the cell gate electrode 112 and the cell gate capping conductive layer 114 are formed. The cell gate insulating layer 111 is shown as being extended along sidewalls of the cell gate capping pattern 113, but is not limited thereto.

The cell gate capping pattern 113 may include at least one of, for example, silicon nitride (SiN), silicon oxynitride (SiON), silicon oxide (SiO₂), silicon carbonitride (SiCN), silicon oxycarbonitride (SiOCN), or a combination thereof.

Although not shown, an impurity doping region may be formed on at least one side of the cell gate structure 110. The impurity doping region may be a source/drain region of a transistor. The impurity doping region may be formed in the storage connection region 103b and the bit line connection region 103a of FIG. 3.

The bit line structure 140ST may include a cell conductive line 140 and a cell line capping layer 144. The cell conductive line 140 may be disposed on the substrate 100, on which the cell gate structure 110 is formed, and the cell element isolation layer 105. The cell conductive line 140 may cross the cell element isolation layer 105 and the cell active region ACT defined by the cell element isolation layer 105. The cell conductive line 140 may be formed to cross the cell gate structure 110.

In this case, the cell conductive line 140 may correspond to the bit line BL. A long sidewall BL_LSW of the bit line may be a long sidewall of the cell conductive line 140, and a short sidewall BL_SSW of the bit line may be a short sidewall of the cell conductive line 140. The longitudinal end BL_EP of the bit line may be a longitudinal end of the cell conductive line 140.

The cell conductive line 140 may be extended to the first portion 22R1 of the cell region isolation layer and the isolation active region 25. The cell conductive line 140 may include a first portion and a second portion, which do not overlap the cell region 20 in the fourth direction D4.

The first portion of the cell conductive line 140 may be disposed on the first portion 22R1 of the cell region isolation layer. The first portion of the cell conductive line 140 may overlap the first portion 22R1 of the cell region isolation layer in the fourth direction D4.

The second portion of the cell conductive line 140 may be disposed on the isolation active region 25. The second portion of the cell conductive line 140 may overlap the isolation active region 25 in the fourth direction D4. The second portion of the cell conductive line 140 may include a longitudinal end of the cell conductive line 140, that is, the longitudinal end BL_EP of the bit line.

The cell conductive line 140 is extended along an upper surface of the first sub-region isolation layer 22R1_1, but may not extend along an upper surface of the second sub-region isolation layer 22R1_2. In other words, the cell conductive line 140 may overlap the first sub-region isolation layer 22R1_1 in the fourth direction D4. The cell conductive line 140 may not overlap the second sub-region isolation layer 22R1_2 in the fourth direction D4.

The cell conductive line 140 may be a multi-layer. The cell conductive line 140 may include, for example, a first cell conductive layer 141, a second cell conductive layer 142, and a third cell conductive layer 143. The first to third cell conductive layers 141, 142 and 143 may be sequentially stacked on the substrate 100 and the cell element isolation layer 105. Although the cell conductive line 140 is shown as being a triple layer, the present disclosure is not limited thereto.

Each of the first to third cell conductive layers 141, 142 and 143 may include at least one of, for example, a semiconductor material doped with impurities, a conductive silicide compound, a conductive metal nitride, metal, or a metal alloy. For example, the first cell conductive layer 141 may include a doped semiconductor material. The first cell conductive layer 141 may be a semiconductor conductive line. The second cell conductive layer 142 may include at least one of a conductive silicide compound, a conductive metal nitride, or a two-dimensional material. The third cell conductive layer 143 may include at least one of a metal or a metal alloy. The second cell conductive layer 142 and the third cell conductive layer 143 may be metallic conductive lines.

In the semiconductor memory device according to some example embodiments, the two-dimensional material may be a metallic material and/or a semiconductor material. The two-dimensional (2D) material may include a two-dimensional allotrope or a two-dimensional compound, and may include at least one of, for example, graphene, molybdenum disulfide (MoS₂), molybdenum diselenide (MoSe₂), tungsten diselenide (WSe₂), tungsten disulfide (WS₂), or tantalum sulfide (TaS₂), but is not limited thereto. That is, since the aforementioned two-dimensional materials are only examples, the two-dimensional material that may be included in the semiconductor device of the present disclosure is not limited by the above-described materials.

The cell line capping layer 144 may be disposed on the cell conductive line 140. The cell line capping layer 144 may be extended in the second direction D2 along an upper surface of the cell conductive line 140. The cell line capping layer 144 may include at least one of, for example, silicon nitride, silicon oxynitride, silicon carbonitride, or silicon oxycarbonitride. In the semiconductor memory device according to some example embodiments, the cell line capping layer 144 may include a silicon nitride layer. The cell line capping layer 144 is shown as a single layer, but is not limited thereto.

That is, the cell line capping layer 144 may be formed by patterning a lower cell capping layer 144p, a second etch stop layer 255, and an insertion peripheral interlayer insulating layer 291. That is, the cell line capping layer 144 may be a multi-layer. However, when layers constituting the multi-layer have the same material, the cell line capping layer 144 may be viewed as a single layer.

The bit line contact 146 may be disposed between the cell conductive line 140 and the substrate 100. That is, the cell conductive line 140 may be disposed on the bit line contact 146. For example, the bit line contact 146 may be disposed at a point where the cell conductive line 140 crosses a center portion of the cell active region ACT having a long island shape, for example a long narrow shape. The bit line contact 146 may be disposed between the bit line connection region 103a of the cell active region ACT and the cell conductive line 140. The bit line contact 146 may be connected to the bit line connection region 103a.

A plurality of bit line contacts 146 may be disposed along the second direction D2. Each cell conductive line 140 may be disposed on the plurality of bit line contacts 146, and each cell conductive line 140 may be extended in the second direction D2.

The bit line contact 146 may electrically connect the cell conductive line 140 to the substrate 100. In this case, the bit line contact 146 may correspond to the direct contact DC. The bit line contact 146 may include at least one of, for example, a semiconductor material doped with impurities, a conductive silicide compound, a conductive metal nitride, or a metal.

In FIGS. 6 and 7 in which the cell conductive line 140 is shown, in an area overlapped with an upper surface of the bit line contact 146, the cell conductive line 140 may include a second cell conductive layer 142 and a third cell conductive layer 143. In an area that is not overlapped with the upper surface of the bit line contact 146, the cell conductive line 140 may include first to third cell conductive layers 141, 142 and 143.

The cell insulating layer 130 may be disposed on the substrate 100 and the cell element isolation layer 105. In more detail, the cell insulating layer 130 may be disposed on the substrate 100 on which the bit line contact 146 is not formed and the cell element isolation layer 105. The cell insulating layer 130 may be disposed between the substrate 100 and the cell conductive line 140 and between the cell element isolation layer 105 and the cell conductive line 140. For example, the upper surface of the bit line contact 146 may be higher than an upper surface of the cell insulating layer 130 based on an upper surface of the substrate 100.

The cell insulating layer 130 may be a single layer, but alternatively the cell insulating later 130 may be a multi-layer that includes a first cell insulating layer 131 and a second cell insulating layer 132 as shown. For example, the first cell insulating layer 131 may include a silicon oxide layer, and the second cell insulating layer 132 may include a silicon nitride layer, but the present disclosure is not limited thereto. Unlike the shown example, the cell insulating layer 130 may include three or more insulating layers. When the cell insulating layer 130 includes a third cell insulating layer, the third cell insulating layer may be a silicon oxide layer.

A first bit line spacer 150 may be disposed on a sidewall of the cell conductive line 140 and a sidewall of the cell line capping layer 144. The first bit line spacer 150 may be extended along a long sidewall of the cell conductive line 140.

In a portion of the cell conductive line 140, in which the bit line contact 146 is formed, the first bit line spacer 150 may be formed on the substrate 100 and the cell element isolation layer 105. The first bit line spacer 150 may be disposed on sidewalls of the cell conductive line 140, the cell line capping layer 144 and the bit line contact 146.

In the other portion of the cell conductive line 140, in which the bit line contact 146 is not formed, the first bit line spacer 150 may be disposed on the cell insulating layer 130. The first bit line spacer 150 may be disposed on the sidewalls of the cell conductive line 140 and the cell line capping layer 144.

The first bit line spacer 150 is shown as a single layer, but is not limited thereto. That is, unlike the shown example, the first bit line spacer 150 may have a multi-layered structure. The first bit line spacer 150 may include one of, for example, a silicon oxide layer, a silicon nitride layer, a silicon oxynitride (SiON) layer, a silicon oxycarbonitride (SiOCN) layer, air, and their combination, but is not limited thereto.

A second bit line spacer 155 may be disposed on a short sidewall of the cell conductive line 140. The second bit line spacer 155 may be disposed on the isolation active region 25. The second bit line spacer 155 may not be disposed on the sidewall of the cell line capping layer 144. For example, the second bit line spacer 155 may not vertically overlap the cell line capping layer 144.

The second bit line spacer 155 may include a first sub-cell spacer 156 and a second sub-cell spacer 157. The first sub-cell spacer 156 may be disposed between the cell conductive line 140 and the second sub-cell spacer 157. For example, the first sub-cell spacer 156 may be in contact with the short sidewall of the cell conductive line 140.

For example, the first sub-cell spacer 156 may include silicon nitride. The second sub-cell spacer 157 may include silicon oxide.

A fence pattern 170 may be disposed on the substrate 100 and the cell element isolation layer 105. The fence pattern 170 may be formed to overlap the substrate 100 and the cell gate structure 110 formed in the cell element isolation layer 105. The fence pattern 170 may be disposed between the cell conductive lines 140 extended in the second direction D2. The fence pattern 170 may include at least one of, for example, silicon oxide, silicon nitride, silicon oxynitride, or their combination.

The plurality of storage contacts 120 may be disposed between the cell conductive lines 140 adjacent to each other in the first direction D1. The storage contact 120 may be disposed between the fence patterns 170 adjacent to each other in the second direction D2. The storage contact 120 may overlap the substrate 100 and the cell element isolation layer 105 between the adjacent cell conductive lines 140. The storage contact 120 may be connected to the storage connection region 103b of the cell active region ACT. In this case, the storage contact 120 may correspond to the buried contact BC.

The storage contact 120 may include at least one of, for example, a semiconductor material doped with impurities, a conductive silicide compound, a conductive metal nitride, or a metal.

The storage pad 160 may be disposed on each storage contact 120. The storage pad 160 may be electrically connected to the storage contact 120. The storage pad 160 may be connected to the storage connection region 103b of the cell active region ACT. In this case, the storage pad 160 may correspond to the landing pad LP.

The storage pad 160 may overlap a portion of the upper surface of the cell conductive line 140. The storage pad 160 may include at least one of, for example, a conductive metal nitride, a conductive metal carbide, a metal, or a metal alloy.

A pad isolation insulating layer 180 may be formed on the storage pad 160 and the cell conductive line 140. For example, the pad isolation insulating layer 180 may be disposed on the cell line capping layer 144. The pad isolation insulating layer 180 may define the storage pad 160 that forms a plurality of isolation regions. The pad isolation insulating layer 180 may not cover an upper surface of the storage pad 160. The pad isolation insulating layer 180 may fill a pad isolation recess. The pad isolation recess may isolate adjacent storage pads 160 from each other.

The pad isolation insulating layer 180 includes an insulating material, and may electrically isolate the plurality of storage pads 160 from each other. For example, the pad isolation insulating layer 180 may include at least one of, for example, a silicon oxide layer, a silicon nitride layer, a silicon oxynitride layer, a silicon oxycarbonitride layer, or a silicon carbonitride layer, but is not limited thereto.

A first etch stop layer 295 may be disposed on the pad isolation insulating layer 180 and the storage pad 160. The first etch stop layer 295 may be extended to the peripheral region 24 as well as the cell region 20. The first etch stop layer 295 may include at least one of, for example, a silicon nitride layer, a silicon carbonitride layer, a silicon boron nitride (SiBN) layer, a silicon oxynitride layer, or a silicon oxycarbide layer.

The information storage 190 may be formed on the storage pad 160. The information storage 190 may be electrically connected to the storage pad 160. A portion of the information storage 190 may be disposed in the first etch stop layer 295. The information storage 190 may include, for example, a capacitor, but is not limited thereto. The information storage 190 includes a lower electrode 191, a capacitor dielectric layer 192, and an upper electrode 193.

The lower electrode 191 may be disposed on the storage pad 160. The lower electrode 191 is shown as having a pillar shape, but is not limited thereto. The lower electrode 191 may have a cylinder shape. The capacitor dielectric layer 192 is disposed on the lower electrode 191. The capacitor dielectric layer 192 may be formed along a profile of the lower electrode 191. The upper electrode 193 is disposed on the capacitor dielectric layer 192. The upper electrode 193 may surround outer sidewalls of the lower electrode 191.

For example, the capacitor dielectric layer 192 may be disposed in a portion overlapped with the upper electrode 193 in the fourth direction D4. For another example, unlike the shown example, the capacitor dielectric layer 192 may include a first portion overlapped with the upper electrode 193 in the fourth direction D4 and a second portion that is not overlapped with the upper electrode 193 in the fourth direction D4. That is, the second portion of the capacitor dielectric layer 192 may include a portion that is not covered by the upper electrode 193.

Each of the lower electrode 191 and the upper electrode 193 may include, for example, a doped semiconductor material, a conductive metal nitride (e.g., titanium nitride, tantalum nitride, niobium nitride or tungsten nitride), a metal (e.g., ruthenium, iridium, titanium or tantalum), and a conductive metal oxide (e.g., iridium oxide or niobium oxide), but is not limited thereto.

The capacitor dielectric layer 192 may include one of, for example, silicon oxide, silicon nitride, silicon oxynitride, a high dielectric constant material and their combination, but is not limited thereto. In the semiconductor memory device according to some example embodiments, the capacitor dielectric layer 192 may include a stacked layer structure in which zirconium oxide, aluminum oxide and zirconium oxide are sequentially stacked. In the semiconductor memory device according to some example embodiments, the capacitor dielectric layer 192 may include a dielectric layer containing hafnium (Hf). In the semiconductor memory device according to some example embodiments, the capacitor dielectric layer 192 may have a stacked layer structure of a ferroelectric material layer and a paraelectric material layer.

A peripheral gate structure 240ST may be disposed on the substrate 100 of the peripheral region 24. The peripheral gate structure 240ST may be disposed on a peripheral active region defined by a peripheral element isolation layer. The peripheral gate structure 240ST may be disposed in the peripheral region 24 and included in a peripheral circuit that controls a memory cell formed in the cell region 20.

The peripheral gate structure 240ST may include a peripheral gate insulating layer 230, a peripheral gate conductive layer 240, a peripheral gate capping layer 244, and a peripheral gate spacer 250, which are sequentially stacked on the substrate 100. The peripheral gate spacer 250 may be disposed on a sidewall of the peripheral gate conductive layer 240 and a sidewall of the peripheral gate capping layer 244. The peripheral gate structure 240ST may be the boundary peripheral gate PR_ST of FIG. 4.

The peripheral gate conductive layer 240 may include first to third peripheral conductive layers 241, 242 and 243, which are sequentially stacked on the peripheral gate insulating layer 230. For example, an additional conductive layer may not be disposed between the peripheral gate conductive layer 240 and the peripheral gate insulating layer 230. For another example, unlike the shown example, an additional conductive layer such as a work function conductive layer may be disposed between the peripheral gate conductive layer 240 and the peripheral gate insulating layer 230.

The peripheral gate conductive layer 240 may have the same stacked structure as that of the cell conductive line 140. The first peripheral conductive layer 241 may include the same material as that of the first cell conductive layer 141. The second peripheral conductive layer 242 may include the same material as that of the second cell conductive layer 142. The third peripheral conductive layer 243 may include the same material as that of the third cell conductive layer 143. However, example embodiments are not limited thereto.

The peripheral gate insulating layer 230 may include, for example, silicon oxide, silicon nitride, silicon oxynitride, or a high dielectric constant material having a dielectric constant higher than that of silicon oxide.

The peripheral gate spacer 250 may include a first sub-peripheral spacer 251 and a second sub-peripheral spacer 252. The first sub-peripheral spacer 251 may be disposed between the peripheral gate conductive layer 240 and the second sub-peripheral spacer 252.

In the semiconductor memory device according to some example embodiments, the peripheral gate spacer 250 may have the same stacked structure as that of the second bit line spacer 155. For example, the first sub-peripheral spacer 251 may be formed of the same material as that of the first sub-cell spacer 156, and may include silicon nitride.

The second sub-peripheral spacer 252 may be formed of the same material as that of the second sub-cell spacer 157, and may include silicon oxide.

The second etch stop layer 255 may be disposed on the substrate 100. The second etch stop layer 255 may be formed along a profile of the peripheral gate structure 240ST. The second etch stop layer 255 may be formed along a profile of the second bit line spacer 155.

The second etch stop layer 255 may include at least one of, for example, a silicon nitride layer, silicon oxynitride, silicon carbonitride, or silicon oxycarbonitride.

A lower peripheral interlayer insulating layer 290 may be disposed on the second etch stop layer 255. The lower peripheral interlayer insulating layer 290 may be disposed on the cell region isolation layer 22 between the cell conductive line 140 and the peripheral gate conductive layer 240.

The lower peripheral interlayer insulating layer 290 may include an oxide-based insulating material. For example, the lower peripheral interlayer insulating layer 290 may include silicon oxide. An upper surface of the lower peripheral interlayer insulating layer 290 may be disposed on the same plane as the second etch stop layer 255 extended along an upper surface of the peripheral gate capping layer 244.

An insertion peripheral interlayer insulating layer 291 may be disposed on the peripheral gate conductive layer 240 and the lower peripheral interlayer insulating layer 290. The insertion peripheral interlayer insulating layer 291 may cover the second etch stop layer 255 and the lower peripheral interlayer insulating layer 290. The first etch stop layer 295 may be disposed on the insertion peripheral interlayer insulating layer 291.

The insertion peripheral interlayer insulating layer 291 may include a material different from that of the lower peripheral interlayer insulating layer 290. The insertion peripheral interlayer insulating layer 291 may include, for example, a nitride-based insulating material. For example, the insertion peripheral interlayer insulating layer 291 may include silicon nitride.

The bit line contact plug 261 may be disposed on the cell conductive line 140. The bit line contact plug 261 may be connected to the cell conductive line 140 by passing through the insertion peripheral interlayer insulating layer 291 and the cell line capping layer 144. The bit line contact plug 261 may be connected to the cell conductive line 140 near the longitudinal end of the cell conductive line 140.

For example, the bit line contact plug 261 may be connected to the cell conductive line 140 on the cell region isolation layer 22. Unlike the shown example, the bit line contact plug 261 may be connected to the cell conductive line 140 on the isolation active region 25. The bit line contact plug 261 may be connected to the peripheral circuit formed in the peripheral region 24.

The bit line contact plug 261 may include the same material as that of the storage pad 160. An upper surface of the bit line contact plug 261 may be disposed on the same plane as an upper surface 160US of the storage pad.

Although not shown, the word line contact plug 262 may be connected to the cell gate electrode 112 by passing through the insertion peripheral interlayer insulating layer 291, the lower peripheral interlayer insulating layer 290 and the cell gate capping pattern 113.

The upper peripheral interlayer insulating layer 292 may be disposed on the first etch stop layer 295. The upper peripheral interlayer insulating layer 292 may cover a sidewall of the upper electrode 193. The upper peripheral interlayer insulating layer 292 includes an insulating material.

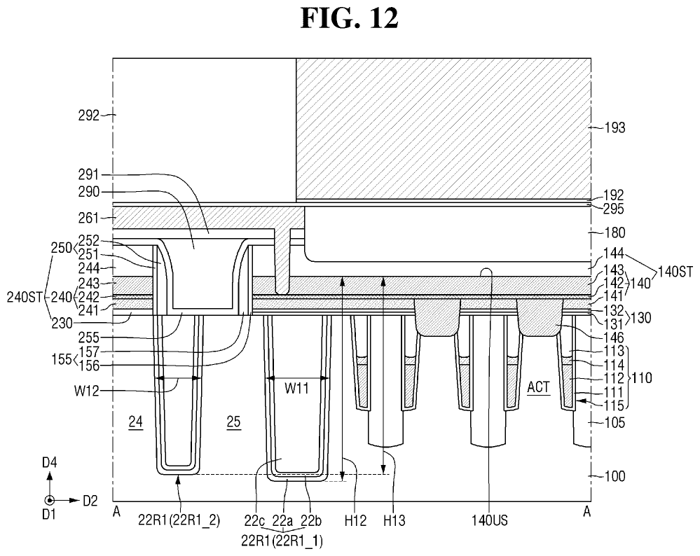

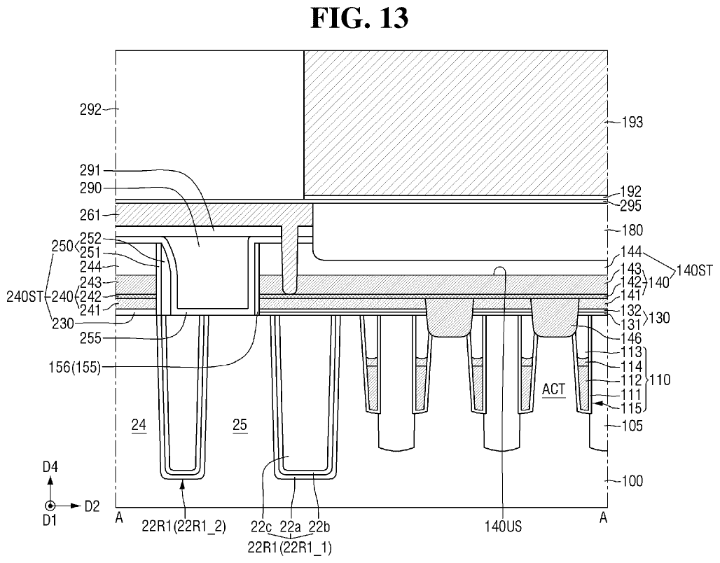

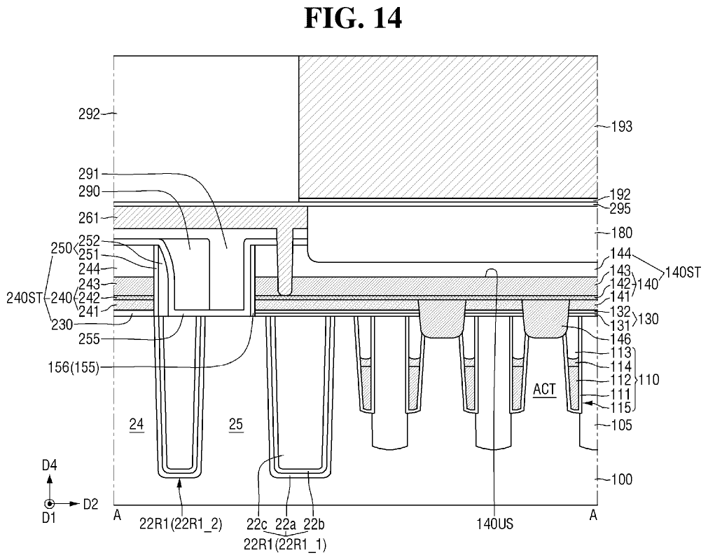

FIG. 12 is a view illustrating a semiconductor memory device according to some example embodiments. FIG. 13 is a view illustrating a semiconductor memory device according to some example embodiments. FIG. 14 is a view illustrating a semiconductor memory device according to some example embodiments. For convenience of description, the following description will be based on differences from the description made with reference to FIGS. 1 to 11.

Referring to FIG. 12, in the semiconductor memory device according to some example embodiments, a depth H12 from the upper surface 140US of the cell conductive line to the lowermost portion of the first sub-region isolation layer 22R1_1 may be greater than a depth H13 from the upper surface 140US of the cell conductive line to the lowermost portion of the second sub-region isolation layer 22R1_2.

For example, a width W11 of the first sub-region isolation layer 22R1_1 in the second direction D2 may be greater than a width W12 of the second sub-region isolation layer 22R1_2 in the second direction D2.

Referring to FIGS. 13 and 14, in the semiconductor memory device according to some example embodiments, a stacked structure of the peripheral gate spacer 250 may be different from that of the second bit line spacer 155.

The second bit line spacer 155 does not include a second sub-cell spacer (157 of FIG. 6) corresponding to the second sub-peripheral spacer 252 of the peripheral gate spacer 250. The second bit line spacer 155 may include a first sub-cell spacer 156 corresponding to the first sub-peripheral spacer 251 of the peripheral gate spacer 250.

The second etch stop layer 255 may be extended along a sidewall of the first sub-cell spacer 156. The second etch stop layer 255 may be in contact with the sidewall of the first sub-cell spacer 156.

In view of a cross-sectional view, the second etch stop layer 255 may include an extension portion extended along an upper surface of the isolation active region 25 and an upper surface of the second sub-region isolation layer 22R1_2.

In FIG. 13, the lower peripheral interlayer insulating layer 290 may fill a space between the peripheral gate spacer 250 and the second bit line spacer 155. The insertion peripheral interlayer insulating layer 291 may not be inserted between the peripheral gate spacer 250 and the second bit line spacer 155. In view of a cross-sectional view, the insertion peripheral interlayer insulating layer 291 is not in contact with the extension portion of the second etch stop layer 255.

In FIG. 14, the insertion peripheral interlayer insulating layer 291 may be inserted between the peripheral gate spacer 250 and the second bit line spacer 155. A portion of the insertion peripheral interlayer insulating layer 291 may be inserted between the short sidewall of the cell conductive line 140 and the lower peripheral interlayer insulating layer 290. In view of a cross-sectional view, the insertion peripheral interlayer insulating layer 291 may be in contact with the extension portion of the second etch stop layer 255.

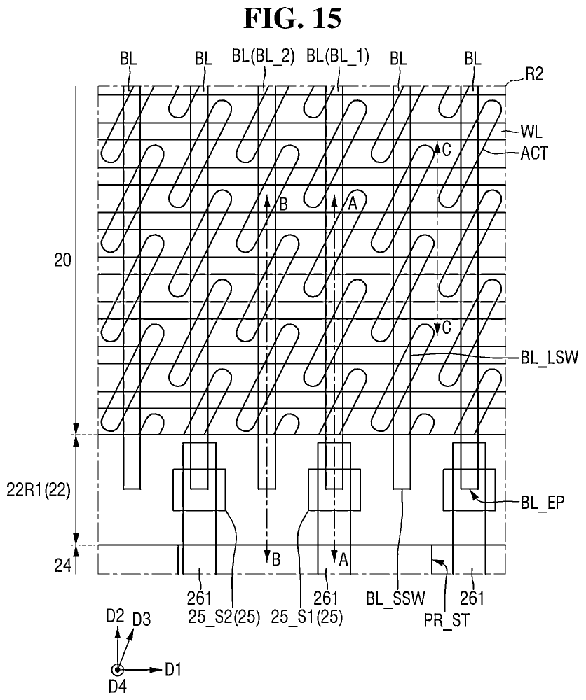

FIG. 15 is a layout view illustrating a semiconductor memory device according to some example embodiments. FIG. 16 is a cross-sectional view taken along line B-B of FIG. 15. For convenience of description, the following description will be based on differences from the description made with reference to FIGS. 1 to 11.

For reference, FIG. 15 is a schematic layout view illustrating a region R2 of FIG. 1. The cross-sectional view taken along line A-A of FIG. 15 may be the same as that of FIG. 6.

Referring to FIGS. 15 and 16, in the semiconductor memory device according to some example embodiments, the isolation active region 25 may include a plurality of sub-isolation active regions 25_S1 and 25_S2, which are spaced apart from each other in the first direction D1.

For example, the plurality of sub-isolation active regions 25_S1 and 25_S2 may include a first sub-isolation active region 25_S1 and a second sub-isolation active region 25_S2. The first sub-isolation active region 25_S1 and the second sub-isolation active region 25_S2 are surrounded by the first portion 22R1 of the cell region isolation layer. The first sub-isolation active region 25_S1 and the second sub-isolation active region 25_S2 may be isolated by the cell region isolation layer 22.

In FIGS. 11 and 15, the first bit line contact plug 261_1 may be connected to the first bit line BL_1 near the first longitudinal end BL_EP1 of the first bit line BL_1. The first longitudinal end BL_EP1 of the first bit line BL_1 connected to the first bit line contact plug 261_1 may be disposed on the first sub-isolation active region 25_S1.

The second bit line contact plug 261_2 may be connected to the second bit line BL_2 near the second longitudinal end BL_EP2 of the second bit line BL_2. The second bit line contact plug 261_2 is not connected to the second bit line BL_2 near the first longitudinal end BL_EP1 of the second bit line BL_2. The first longitudinal end BL_EP1 of the second bit line BL_2 that is not connected to the second bit line contact plug 261_2 may be disposed on the cell region isolation layer 22 between the first sub-isolation active region 25_S1 and the second sub-isolation active region 25_S2. The first longitudinal end BL_EP1 of the second bit line BL_2 that is not connected to the second bit line contact plug 261_2 may be disposed on the first portion 22R1 of the cell region isolation layer.

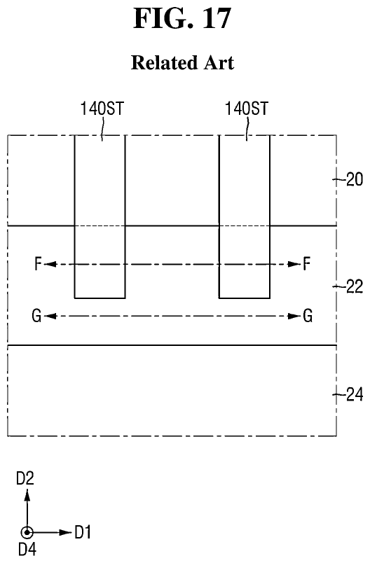

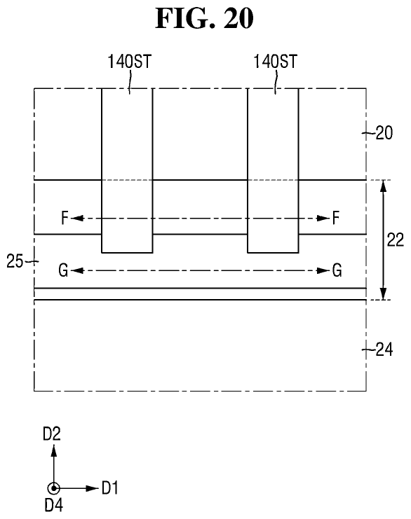

FIGS. 17 to 22 are views illustrating an effect due to arrangement of an isolation active region. FIGS. 17 to 19 are views illustrating problems of the related art. FIGS. 20 to 22 are views illustrating an effect obtained by arrangement of an isolation active region 25 in the cell region isolation layer 22.

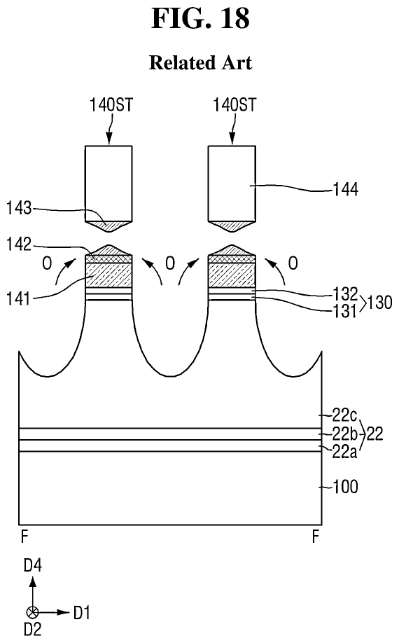

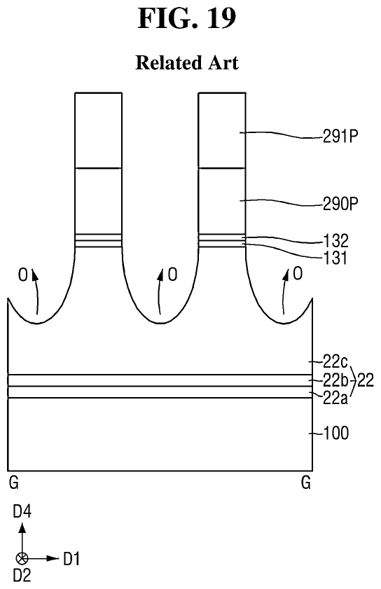

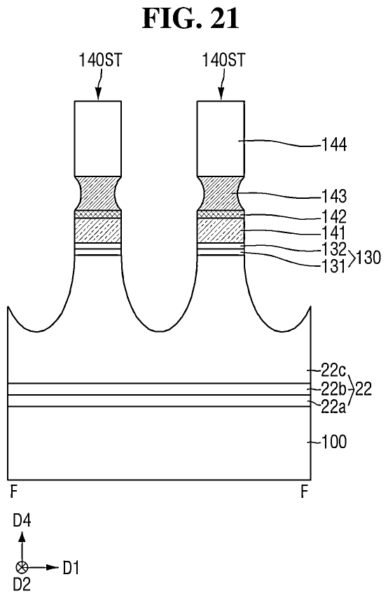

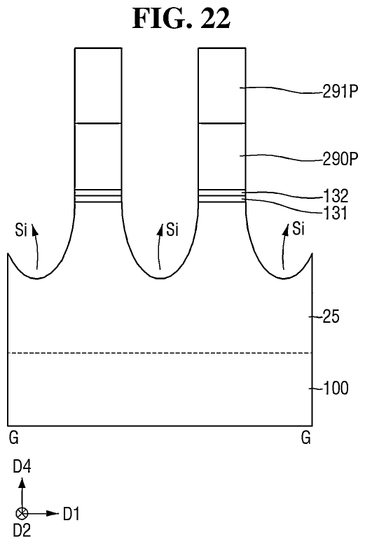

For reference, FIGS. 17 and 20 are brief layout views illustrating effects. FIGS. 18 and 21 are cross-sectional views taken along line F-F of FIGS. 17 and 20. FIGS. 19 and 22 are cross-sectional views taken along line G-G of FIGS. 17 and 20.

In FIGS. 17 to 19, the lower peripheral interlayer insulating layer (290 of FIG. 6) and the insertion peripheral interlayer insulating layer (291 of FIG. 6) may be patterned during an etching process in which the bit line structure 140ST is formed. Therefore, a lower peripheral pattern 290P and an insertion peripheral pattern 291P may be formed.

The lower peripheral pattern 290P and the insertion peripheral pattern 291P may be formed on the cell region isolation layer 22. While the lower peripheral pattern 290P and the insertion peripheral pattern 291P are being formed, a portion of the cell region isolation layer 22 may be also etched so that a recess may be formed in the cell region isolation layer 22. While the cell region isolation layer 22 is being etched, oxygen (O) included in the cell region isolation layer 22 may be torn to the outside. The torn oxygen (O) may excessively etch a portion of the third cell conductive layer 143 included in the bit line structure 140ST.

That is, in the third cell conductive layer 143 included in the bit line structure 140ST, a disconnection of the third cell conductive layer 143 may be generated. In this case, even though the bit line contact plug (261 of FIG. 6) is formed on the cell conductive line (140 of FIG. 6), electrical connection between the bit line contact plug 261 and the cell conductive line 140 may not be stable. Due to the disconnection of the third cell conductive layer 143, performance and reliability of the semiconductor memory device may be deteriorated.

In FIGS. 20 to 22, while an etching process in which the bit line structure 140ST is formed is being performed, the lower peripheral pattern 290P and the insertion peripheral pattern 291P may be formed on the isolation active region 25 made of a semiconductor material.

While the lower peripheral pattern 290P and the insertion peripheral pattern 291P are being formed, a portion of the cell isolation active region 25 may be also etched so that a recess may be formed in the isolation active region 25. However, in the cross-sectional view shown in FIG. 22, while the recess is being formed in the isolation active region 25, oxygen (O) is not torn to the outside. That is, the isolation active region 25 is disposed in the cell region isolation layer 22, so that supply of oxygen (O) in which the third cell conductive layer 143 may be excessively etched is reduced.

That is, in the third cell conductive layer 143 included in the bit line structure 140ST, disconnection of the third cell conductive layer 143 may not occur. Therefore, performance and reliability of the semiconductor memory device may be improved.

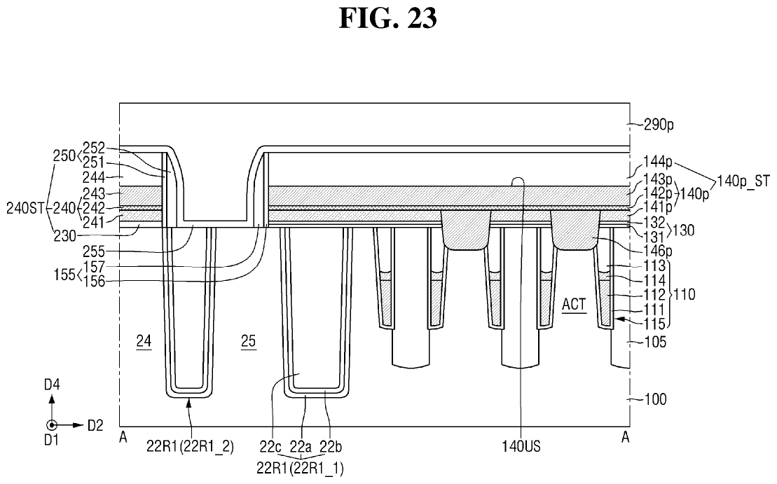

FIGS. 23 to 25 are views illustrating a method for fabricating a semiconductor memory device according to some example embodiments.

FIGS. 23 to 25 may be cross-sectional views taken along line A-A of FIG. 4.

In the description of the fabricating method, portions duplicated with those described with reference to FIGS. 1 to 11 will be briefly described or omitted.

Referring to FIGS. 4 and 23, the cell region isolation layer 22 may be formed in the substrate 100 so that the cell region 20 may be isolated from the peripheral region 24.

In addition, the isolation active region 25 may be defined by the cell region isolation layer 22.

The cell gate structure 110 may be formed in the substrate 100 of the cell region 20. The cell gate structure 110 may be extended to be elongated in the first direction D1. The cell gate structure 110 may include a cell gate trench 115, a cell gate insulating layer 111, a cell gate electrode 112, a cell gate capping pattern 113, and a cell gate capping conductive layer 114.

Then, a cell insulating layer 130 may be formed on the cell region 20. The cell insulating layer 130 may expose the substrate 100 of the peripheral region 24.

Subsequently, a cell conductive layer structure 140p_ST may be formed on the substrate 100 of the cell region 20. The cell conductive layer structure 140p_ST may be formed on the cell insulating layer 130. In addition, a pre-bit line contact 146p may be formed between the cell conductive layer structure 140p_ST and the substrate 100. The pre-bit line contact 146p may connect the cell conductive layer structure 140p_ST with the substrate 100.

The cell conductive layer structure 140p_ST may include a pre-cell conductive layer 140p and a lower cell capping layer 144p, which are sequentially stacked on the cell insulating layer 130. The second bit line spacer 155 may be formed on a sidewall of the cell conductive layer structure 140p_ST.

The peripheral gate structure 240ST may be formed on the substrate 100 of the peripheral region 24. The peripheral gate structure 240ST may include a peripheral gate insulating layer 230, a peripheral gate conductive layer 240, a peripheral gate capping layer 244, and a peripheral gate spacer 250.

The cell conductive layer structure 140p_ST may be formed, for example simultaneously formed, with the peripheral gate conductive layer 240 and the peripheral gate capping layer 244. The second bit line spacer 155 may be formed, for example simultaneously formed, with the peripheral gate spacer 250.

Then, the second etch stop layer 255 may be formed on the substrate 100. The second etch stop layer 255 may be formed on the cell conductive layer structure 140p_ST, the second bit line spacer 155 and the peripheral gate structure 240ST. The second etch stop layer 255 may be extended along an upper surface of the cell conductive layer structure 140p_ST, a profile of the second bit line spacer 155, and a profile of the peripheral gate structure 240ST.

Then, a pre-lower peripheral interlayer insulating layer 290p may be formed on the second etch stop layer 255. The pre-lower peripheral interlayer insulating layer 290p may cover or entirely cover the second etch stop layer 255.

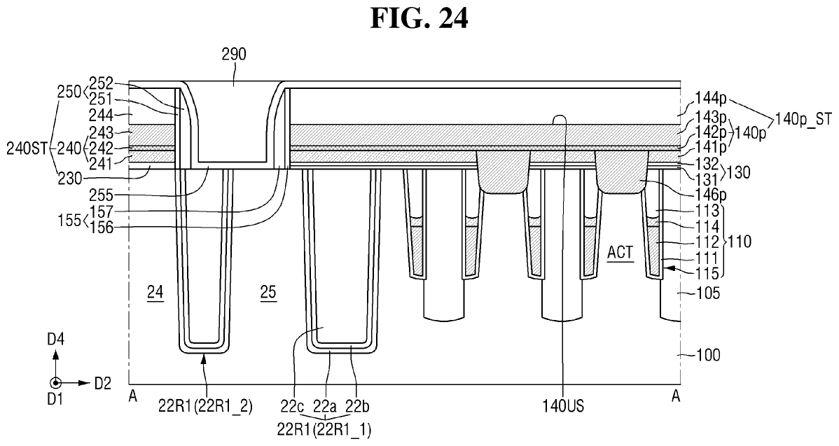

Referring to FIG. 24, the pre-lower peripheral interlayer insulating layer 290p disposed on the upper surface of the cell conductive layer structure 140p_ST and the upper surface of the peripheral gate structure 240ST may be removed. The lower peripheral interlayer insulating layer 290 may be formed on the second etch stop layer 255.

For example, the lower peripheral interlayer insulating layer 290 may be formed using a chemical mechanical polishing (CMP) process. That is, the pre-lower peripheral interlayer insulating layer 290p on the upper surface of the cell conductive layer structure 140p_ST and the upper surface of the peripheral gate structure 240ST may be removed using the chemical mechanical polishing (CMP) process.

As a result, the second etch stop layer 255 on the upper surface of the cell conductive layer structure 140p_ST and the upper surface of the peripheral gate structure 240ST may be exposed.

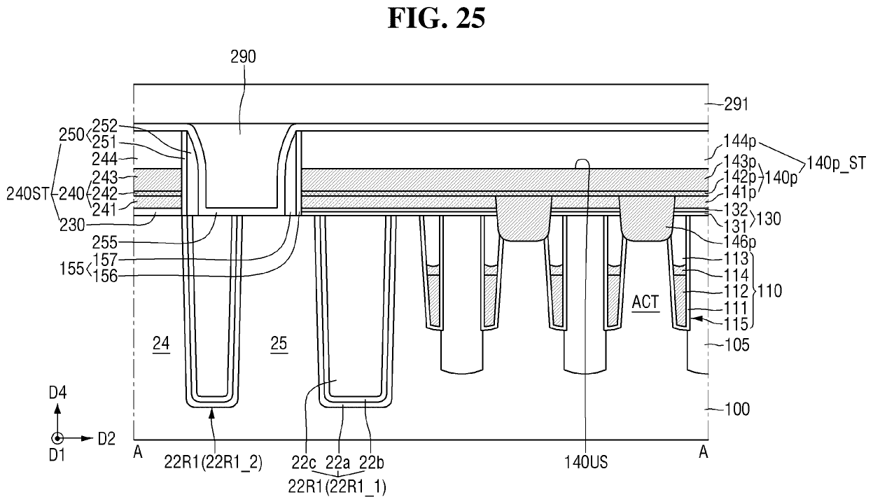

Referring to FIG. 25, the insertion peripheral interlayer insulating layer 291 may be formed on the lower peripheral interlayer insulating layer 290.

The insertion peripheral interlayer insulating layer 291 may be formed on the second etch stop layer 255 on the upper surface of the cell conductive layer structure 140p_ST and the upper surface of the peripheral gate structure 240ST. The insertion peripheral interlayer insulating layer 291 may be formed on the cell region 20 as well as the peripheral region 24.

Referring to back to FIG. 6, the bit line structure 140ST extended in the second direction D2 may be formed by patterning the cell conductive layer structure 140p_ST, and the insertion interlayer insulating layer 291 and the second etch stop layer 255 on the cell region 20.

While the bit line structure 140ST is being formed, the bit line contact 146 may be formed. The first bit line spacer (150 of FIG. 9) may then be formed.

Subsequently, the storage contact (120 of FIG. 9), the storage pad (160 of FIG. 9), and the information storage (190 of FIG. 9) may be formed.

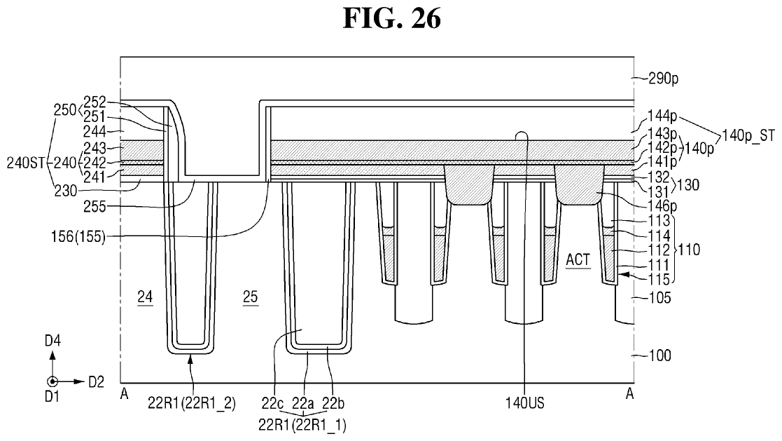

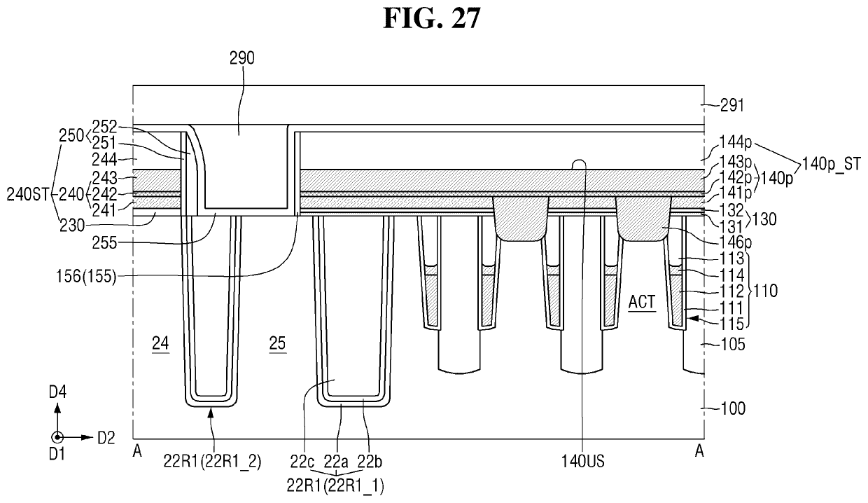

FIGS. 26 and 27 are views illustrating a method for fabricating a semiconductor memory device according to some example embodiments.

FIGS. 26 and 27 may be cross-sectional views taken along line A-A of FIG. 4.

In the description of the fabricating method, portions duplicated with those described with reference to FIGS. 1 to 11 and FIG. 13 will be briefly described or omitted.

Referring to FIG. 26, the cell region isolation layer 22 may be formed in the substrate 100. Therefore, the cell region 20 and the peripheral region 24 may be isolated from each other, and the isolation active region 25 may be defined.

The cell gate structure 110 may be formed in the substrate 100 of the cell region 20. Then, the cell conductive layer structure 140p_ST may be formed on the substrate 100 of the cell region 20. The peripheral gate structure 240ST may be formed on the substrate 100 of the peripheral region 24. The second bit line spacer 155 may be formed on the sidewall of the cell conductive layer structure 140p_ST.

Subsequently, a mask pattern covering the peripheral gate spacer 250 may be formed. The second sub-cell spacer 157 may be removed using the mask pattern. That is, the stacked structure of the peripheral gate spacer 250 may be different from that of the second bit line spacer 155.

The second sub-cell spacer 157 may include silicon oxide. Since the second sub-cell spacer 157 is removed, an oxygen supply source may be reduced while the bit line structure (140ST of FIGS. 20 to 22) is being formed.

Subsequently, the second etch stop layer 255 and the pre-lower peripheral interlayer insulating layer 290p may be formed on the substrate 100.

Referring to FIG. 27, a portion of the pre-lower peripheral interlayer insulating layer 290p may be removed to form the lower peripheral interlayer insulating layer 290.

The insertion peripheral interlayer insulating layer 291 may be formed on the lower peripheral interlayer insulating layer 290.

Referring back to FIG. 13, the bit line structure 140ST extended in the second direction D2 may be formed by patterning the cell conductive layer structure 140p_ST, and the insertion interlayer insulating layer 291 and the second etch stop layer 255 on the cell region 20.

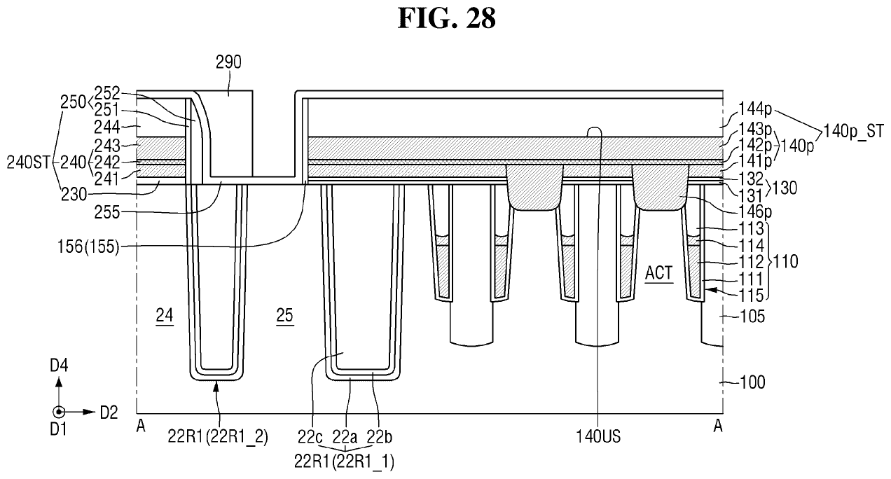

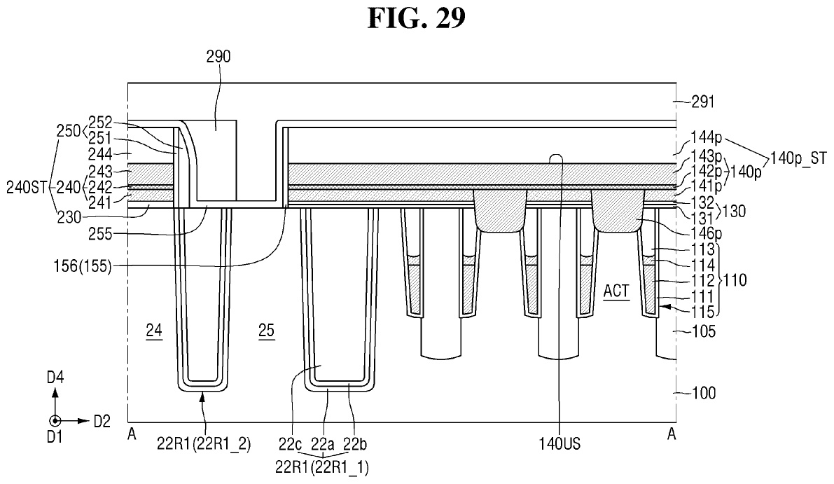

FIGS. 28 and 29 are views illustrating a method for fabricating a semiconductor memory device according to some example embodiments. For reference, FIG. 28 may be a fabricating process step performed after FIG. 26. In the description of the fabricating method, portions duplicated with those described with reference to FIGS. 1 to 11 and FIG. 14 will be briefly described or omitted.

Referring to FIG. 28, a portion of the pre-lower peripheral interlayer insulating layer (290p of FIG. 26) may be removed to form the lower peripheral interlayer insulating layer 290.

Then, a mask pattern covering a portion of the lower peripheral interlayer insulating layer 290 may be formed. A portion of the lower peripheral interlayer insulating layer 290 may be removed using the mask pattern. The lower peripheral interlayer insulating layer 290 of a portion adjacent to the cell conductive layer structure 140p_ST may be removed.

The lower peripheral interlayer insulating layer 290 may include silicon oxide. The lower peripheral interlayer insulating layer 290 of a portion adjacent to the cell conductive layer structure 140p_ST may be removed so that an oxygen supply source may be reduced while the bit line structure (140ST of FIGS. 20 to 22) is being formed.

Referring to FIG. 29, the insertion peripheral interlayer insulating layer 291 may be formed on the lower peripheral interlayer insulating layer 290.

The insertion peripheral interlayer insulating layer 291 may fill a space between the lower peripheral interlayer insulating layer 290 and the cell conductive layer structure 140p_ST.

Referring to FIG. 14, the bit line structure 140ST extended to be elongated in the second direction D2 may be formed by patterning the cell conductive layer structure 140p_ST, and the insertion interlayer insulating layer 291 and the second etch stop layer 255 on the cell region 20.

Although the example embodiments of the present disclosure have been described with reference to the accompanying drawings, the present disclosure is not limited to the above example embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the example embodiments as described above are not restrictive but illustrative in all respects.

What is claimed is:

1. A semiconductor memory device comprising:
a substrate including a cell region and a peripheral region;
a cell region isolation layer in the substrate, isolating the cell region from the peripheral region;
an isolation active region surrounded by the cell region isolation layer;
a bit line structure on the cell region, including a cell conductive line; and
a cell gate electrode in the substrate of the cell region, crossing the cell conductive line.

2. The semiconductor memory device of claim 1, wherein the cell region isolation layer includes a first portion extending in a first direction and a second portion extending in a second direction orthogonal to the first direction, and
in a plan view, the isolation active region is in the first portion of the cell region isolation layer and is not in the second portion of the cell region isolation layer.

3. The semiconductor memory device of claim 2, wherein the cell conductive line extends in the second direction, and
the cell gate electrode extends in the first direction.

4. The semiconductor memory device of claim 3, wherein a portion of the cell conductive line overlaps the first portion of the cell region isolation layer in a third direction.

5. The semiconductor memory device of claim 3, wherein a portion of the cell gate electrode overlaps the second portion of the cell region isolation layer in a third direction.

6. The semiconductor memory device of claim 1, wherein the cell conductive line includes a long sidewall extending in a first direction and a short sidewall extending in a second direction, and a portion of the cell conductive line overlaps the isolation active region in a third direction.

7. The semiconductor memory device of claim 6, wherein the cell conductive line includes a longitudinal end that includes the short sidewall of the cell conductive line, and the longitudinal end of the cell conductive line is on the isolation active region.

8. The semiconductor memory device of claim 1, wherein the cell conductive line extends in a first direction,
the isolation active region includes a first sub-isolation active region and a second sub-isolation active region, which are spaced apart from each other in a second direction orthogonal to the first direction, and
the first sub-isolation active region and the second sub-isolation active region are surrounded by the cell region isolation layer.

9. The semiconductor memory device of claim 1, further comprising:
a peripheral gate structure on the substrate of the peripheral region, including a peripheral gate conductive layer, a peripheral gate capping layer and a peripheral gate spacer;
a bit line spacer on a short sidewall of the cell conductive line; and
an etch stop layer that extends along a profile of the peripheral gate spacer, an upper surface of the peripheral gate capping layer and an upper surface of the cell region isolation layer,
wherein the peripheral gate spacer includes a first peripheral gate spacer and a second peripheral gate spacer, which include their respective materials different from each other,
the first peripheral gate spacer is between the peripheral gate conductive layer and the second peripheral gate spacer, and
a stacked structure of the bit line spacer is different from that of the peripheral gate spacer.

10. The semiconductor memory device of claim 9, further comprising:
a peripheral interlayer insulating layer between the short sidewall of the cell conductive line and the peripheral gate structure, the peripheral interlayer insulating layer on the etch stop layer; and
an insertion interlayer insulating layer covering the peripheral interlayer insulating layer and the peripheral gate structure and including a material different from that of the peripheral interlayer insulating layer,
wherein a portion of the insertion interlayer insulating layer is between the cell conductive line and the peripheral interlayer insulating layer.

11. A semiconductor memory device comprising:
a substrate including a cell region and a peripheral region;
a cell region isolation layer in the substrate, including a first sub-region isolation layer and a second sub-region isolation layer, which are spaced apart from each other in a first direction, and isolating the cell region from the peripheral region;
an isolation active region between the first sub-region isolation layer and the second sub-region isolation layer;
a cell conductive line on the cell region and extending in the first direction; and
a cell gate electrode in the substrate of the cell region and extending in a second direction.

12. The semiconductor memory device of claim 11, wherein the first sub-region isolation layer is closer to the cell region than the second sub-region isolation layer, and
the cell conductive line overlaps the first sub-region isolation layer in a third direction and does not overlap the second sub-region isolation layer in the third direction.

13. The semiconductor memory device of claim 12, wherein a portion of the cell conductive line is on the isolation active region.

14. The semiconductor memory device of claim 11, wherein the cell region includes a plurality of cell active regions defined by a cell element isolation layer, and
a depth from an upper surface of the cell conductive line to a lowermost portion of the cell element isolation layer is smaller than that from the upper surface of the cell conductive line to a lowermost portion of the first sub-region isolation layer.

15. The semiconductor memory device of claim 11, wherein a width of the first sub-region isolation layer in the first direction is different from that of the second sub-region isolation layer in the first direction, and
a depth from an upper surface of the cell conductive line to a lowermost portion of the first sub-region isolation layer is the same as that from the upper surface of the cell conductive line to a lowermost portion of the second sub-region isolation layer.

16. The semiconductor memory device of claim 11, wherein a width of the first sub-region isolation layer in the first direction is greater than that of the second sub-region isolation layer in the first direction, and
a depth from an upper surface of the cell conductive line to a lowermost portion of the first sub-region isolation layer is greater than that from the upper surface of the cell conductive line to a lowermost portion of the second sub-region isolation layer.

17. The semiconductor memory device of claim 11, wherein each of the first sub-region isolation layer and the second sub-region isolation layer includes
a filling isolation layer, and
a liner isolation layer extended along sidewalls and a bottom surface of the filling isolation layer.

18. A semiconductor memory device comprising:
a substrate including a cell region and a peripheral region;
a cell region isolation layer in the substrate, isolating the cell region from the peripheral region;
an isolation active region surrounded by the cell region isolation layer;
a plurality of cell conductive lines on the cell region and extending in a first direction;
a plurality of cell gate electrodes in the substrate of the cell region and extending in a second direction; and
a plurality of cell conductive plugs on the cell conductive line and respectively connected to the cell conductive lines,
wherein each cell conductive line includes a first longitudinal end and a second longitudinal end,
the first longitudinal end of the cell conductive line is spaced apart from the second longitudinal end of the cell conductive line in the first direction,
the plurality of cell conductive lines include a first cell conductive line and a second cell conductive line, which are adjacent to each other in the second direction,
the first longitudinal end of the first cell conductive line is on the isolation active region, and
the first longitudinal end of the second cell conductive line is on the cell region isolation layer.

19. The semiconductor memory device of claim 18, wherein the cell conductive plugs includes a first cell conductive plug connected to the first cell conductive line and a second cell conductive plug connected to the second cell conductive line,
the first cell conductive plug is connected to the first cell conductive line near the first longitudinal end of the first cell conductive line, and
the second cell conductive plug is connected to the second cell conductive line near the second longitudinal end of the second cell conductive line.

20. The semiconductor memory device of claim 18, wherein the isolation active region includes a plurality of sub-isolation active regions spaced apart from each other in the second direction and surrounded by the cell region isolation layer,
the first longitudinal end of the first cell conductive line is on the sub-isolation active region, and
the first longitudinal end of the second cell conductive line is on the cell region isolation layer between adjacent sub-isolation active regions.
